(19) United States
(12) Patent Application Publication
(10) Pub. No.: US 2007/0212867 A1
(43) Pub. Date: Sep. 13, 2007

(54) Method and structure for improving bonding reliability in bond pads

(75) Inventors: Hsien-Wei Chen, Tainan (TW); Jun-Ren Chen, Hsinchu (TW)

Correspondence Address: BIRCH, STEWART, KOLASCH & BIRCH, LLP, PO BOX 747, 8110 GATEHOUSE RD, STE 500 EAST, FALLS CHURCH, VA, 22040-0747, US

(73) Assignee: TAIWAN SEMICONDUCTOR MANUFACTURING CO., LTD.

(21) Appl. No.: 11/368,380

(22) Filed: Mar. 7, 2006

(51) Int. Cl. H01L 21/44

(52) U.S. Cl. 438/613

(57) ABSTRACT

A method for fabricating a bond pad structure in an integrated circuit is provided. In one embodiment, a bond pad is formed above a substrate. A first passivation layer is deposited above the bond pad, the first passivation having an opening therein exposing a portion of the bond pad. A conductive layer is deposited over the first passivation layer and the exposed bond pad. The conductive layer is patterned to expose portions of the first passivation layer. A second passivation layer is deposited above the conductive layer and the exposed first passivation layer, the second passivation layer having an opening therein exposing a portion of the conductive layer. An electrical contact is bonded to the exposed portion of the conductive layer.

### BACKGROUND

The present invention relates generally to packaging of semiconductor devices, and more particularly, to a method and structure for improving bonding reliability in bond pads.

Wirebonding is a common technique for establishing electrical connection between bond pads on the surface of a chip or die and the inner lead terminals on a leadframe or substrate. A section of a typical conventional wirebonded chip 2 is shown schematically in FIG. 1 and may include multiple wire bonding balls 4, each of which is directly bonded to the continuous upper surface of a bond pad 6, typically rectangular in configuration and partially covered by a first passivation layer 8. A pad opening in the passivation layer 8 exposes the bond pad 6. The bond pad 6 is surrounded by a dielectric layer 10 such as an oxide in the chip 2. As further shown in FIG. 1, the bond pad 6 is provided in electrical contact with an upper conductive layer 12, which is separated from an underlying conductive layer 14 by an insulative layer 16. The conductive layers 12 and 14 are disposed in electrical contact with each other through conductive vias 18 that extend through the insulative layers 16. The various insulative layers 16 and conductive layers 14 are sequentially deposited on a silicon substrate 20 throughout semiconductor fabrication, in conventional fashion. Each bonding ball 4 connects a bonding wire 22 through a lead to the terminals (not shown) on a leadframe.

The bond pads 6 are typically arranged in rows which extend adjacent to respective edges of the chip 2. Prior to packaging and formation of the bonding balls 4 on the respective bond pads 6, the chip 2 is subjected to parametric testing which utilizes test structures to assess the electrical characteristics and reliability of the devices or circuits on the wafer. Probe cards (not shown) are typically used as an interface between the devices on the chip and automated test equipment (not shown). The probe card typically includes a printed circuit board from which extends multiple probe needles (not shown), each of which is disposed in electrical contact with the chip 2 through the respective bond pads 6. During the parametric testing procedure, each probe needle typically contacts the approximate center of the bond pad 6 at a pressure of typically about 2-3 grams. Consequently, the probe needle typically forms a scrub mark (not shown) in the center of the bond pad 6. The surfaces of the bond pads 6 are frequently damaged during the parametric testing procedure. The damaged surface will result in a lower contact adhesion between the respective bond pad and bonding ball and therefore lower bonding reliability therebetween.

After the chip 2 is subjected to parametric testing, the bonding balls 4 are formed on the respective bond pads 6 and a bonding wire 22 is bonded to each bonding ball 4, as shown in FIG. 1. Alternatively, each bonding wire 22 may be bonded directly to the surface of each bond pad 6. The chip 2 may then be subjected to physical pressure tests in which shear and other forces are applied to the bonding wire 22 and bond pad 6. One of the problems which typically occurs during such testing is that each bond pad 6 tends to exert pressure against the surrounding and lower dielectric layers, such as the adjacent dielectric layer 10, forming cracks or otherwise damaging the dielectric layer 10 in the region surrounding the bond pad 6. Also, as mentioned above, as the bonding balls 4 are formed on or near the scrub mark on the surface of the bond pad 6, this results in a weaker and less reliable mechanical bond.

For these reasons and other reasons that will become apparent upon reading the following detailed description, there is a need for a bond pad structure having improved bonding reliability and reduced damage to the wirebonded chip during the testing and bonding processes.

### SUMMARY

The present invention is directed to a method for fabricating a bond pad structure in an integrated circuit. In one embodiment, a bond pad is formed above a substrate. A first passivation layer is deposited above the bond pad, the first passivation having an opening therein exposing a portion of the bond pad. A conductive layer is deposited over the first passivation layer and the exposed bond pad. The conductive layer is patterned to expose portions of the first passivation layer. A second passivation layer is deposited above the conductive layer and the exposed first passivation layer, the second passivation layer having an opening therein exposing a portion of the conductive layer. An electrical contact is bonded to the exposed portion of the conductive layer.

### BRIEF DESCRIPTION OF THE DRAWINGS

The features, aspects, and advantages of the present invention will become more fully apparent from the following detailed description, appended claims, and accompanying drawings in which:

FIG. 1 is a cross-sectional view of a section of a conventional wirebonded chip, illustrating a conventional technique for bonding a bonding ball to a bond pad.

FIG. 2 is a cross-sectional view of a section of a wirebonded chip, illustrating the steps of providing a bond pad formed above a substrate and depositing a first passivation layer above the bond pad according to one embodiment of the present invention.

FIG. 3 is a cross-sectional view of the wirebonded chip of FIG. 2, illustrating a further step of depositing a conductive layer over the first passivation layer and the exposed bond pad according to one embodiment of the present invention.

FIG. 4 is a cross-sectional view of the wirebonded chip of FIG. 3, illustrating further steps of patterning the conductive layer to expose portions of the first passivation layer and performing a probe needle contact on the bond pad according to one embodiment of the present invention.

FIG. 5 is a cross-sectional view of the wirebonded chip of FIG. 4, illustrating a further step of depositing a second passivation layer above the conductive layer and the exposed first passivation layer, the second passivation layer having an opening therein exposing a portion of the conductive layer according to one embodiment of the present invention.

FIG. 6 is a cross-sectional view of the wirebonded chip of FIG. 5, illustrating a further step of bonding an electrical contact to the exposed portion of the conductive layer according to one embodiment of the present invention.

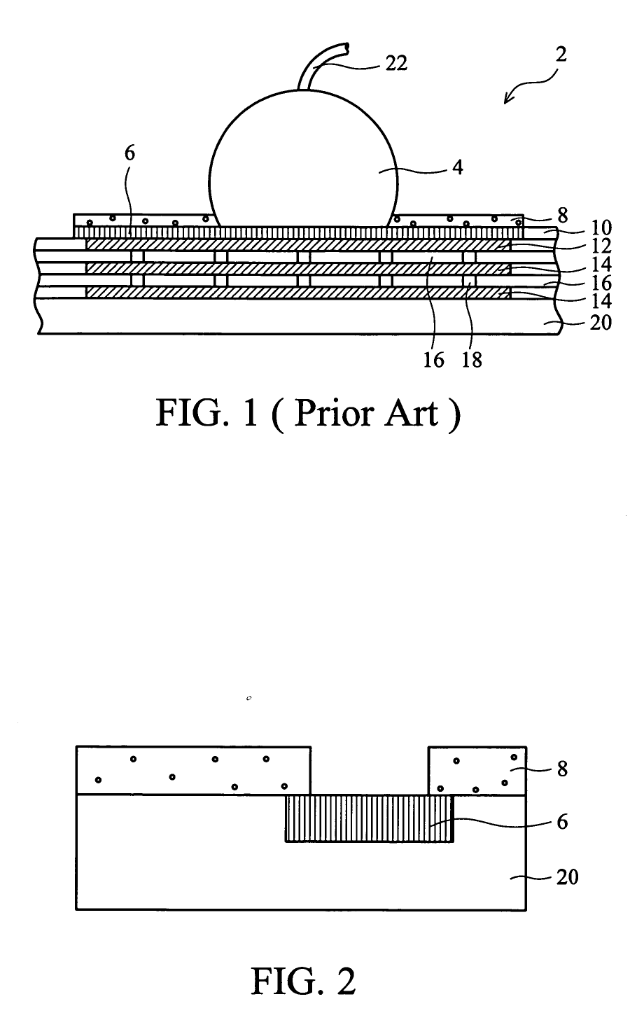

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

The present invention has particular beneficial utility in a bond pad structure that results in improved bonding reliability and reduced damage to the wirebonded chip during the testing and bonding procedures.

Referring initially to FIG. 2, a cross-sectional view of a section of a wirebonded chip is shown, illustrating the steps of providing a bond pad formed above a substrate and depositing a first passivation layer above the bond pad according to one embodiment of the present invention. As one skilled in the art will recognize, substrate 20 may include active devices (not shown) such as a combination of gates, source and drain regions, etc., which constitute semiconductor circuits that may be designed to perform a variety of functions. Above the active devices, are sequentially deposited conductive layers (not shown) and insulative layers (not shown) in alternating fashion. The conductive layers may be aluminum or other conductive meals suitable for use in semiconductor devices. The conductive and insulative layers may be deposited on the substrate 20 using chemical vapor deposition (CVD) techniques, as is well-known by those skilled in the art. Conductive vias (not shown) extend through the insulative layers to establish electrical contact between adjacent conductive layers in the chip. A bond pad 6, which may be aluminum, copper, or other electrically-conductive material, is provided in substrate 20. A first passivation layer 8 is next deposited above substrate 20 and then patterned to form an opening therein exposing a portion of bond pad 6. First passivation layer 8 electrically isolates bond pad 6 from the conductive layers. In the completely assembled and packaged chip, electrical current is passed to the bond pad 6, conductive vias and conductive layers from a substrate or leadframe (not shown) through a bond wire to impart functionality to the chip.

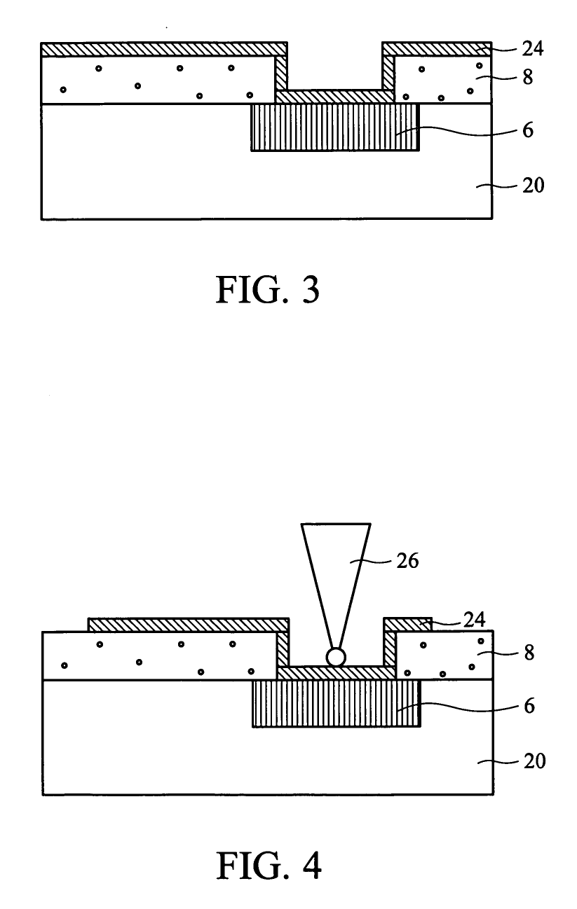

FIG. 3 is a cross-sectional view of the wirebonded chip of FIG. 2, illustrating a further step of depositing a conductive layer over the first passivation layer and the exposed bond pad according to one embodiment of the present invention. Conductive layer 24 may comprise aluminum, copper, or other electrically-conductive materials and may be deposited by well-known CVD or sputtering techniques and may have a thickness of from about 8,000 angstroms to about 14,000 angstroms. After deposition, conductive layer 24 is thereafter patterned by well-known lithographic techniques to expose portions of the first passivation layer 8, as shown in FIG. 4.

Prior to packaging and formation of the bonding balls on the respective bond pads 6, the chip is subjected to parametric testing which utilizes test structures to assess the electrical characteristics and reliability of the devices or circuits on the wafer. Probe cards (not shown) are typically used as an interface between the devices on the chip and automated test equipment (not shown). The probe card's printed circuit board extends multiple probe needles 26, each of which is disposed in electrical contact with the chip through the respective bond pads 6. During the parametric testing procedure, each probe needle 26 typically contacts the approximate center of the bond pad 6 at a pressure of typically about 2-3 grams. Consequently, the probe needle 26 typically forms a scrub mark (not shown) in the center of the bond pad 6. As mentioned previously, surfaces of the bond pads 6 are frequently damaged during the parametric testing procedure. The damaged surface will result in a lower contact adhesion between the respective bond pad and a later to be formed electrical contact (e.g., bonding balls and bonding wires) and therefore lower bonding reliability therebetween. However, as will be shown below, a chip formed in accordance with the principals of the present invention will not suffer from the conventional bonding reliability problems as the electrical contacts are not formed on or near the scrub mark on the surface of the bond pad 6 but instead they are bonded to a conductive layer at a position distal from bond pad 6.

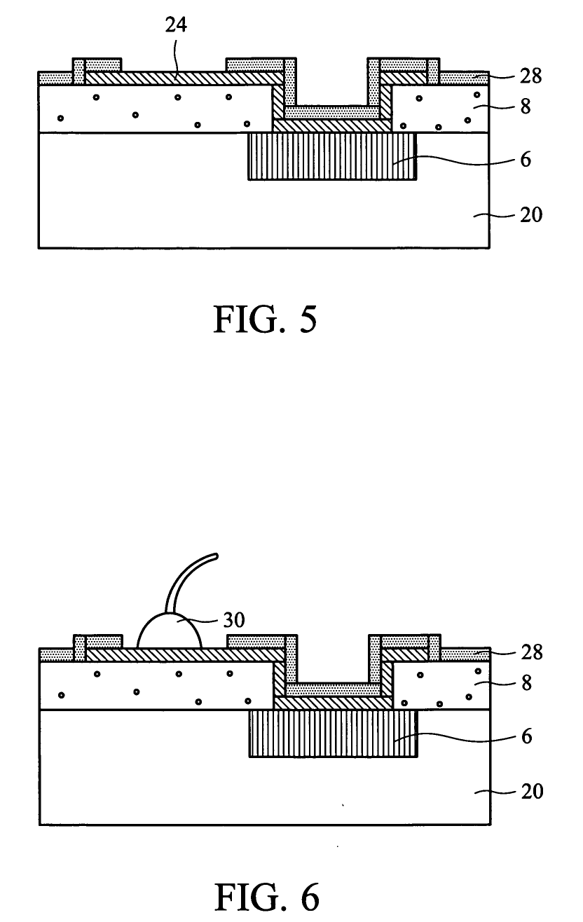

After the chip has been subjected to parametric testing, bonding balls or bonding wires will need to be formed on the respective bond pads 6. Prior to this step, however, as shown in FIG. 5, a cross-sectional view of the wirebonded chip of FIG. 4 illustrates the further step of depositing a second passivation layer 28 above the conductive layer 24 and the exposed first passivation layer 8. Second passivation layer 28 is deposited using conventional CVD techniques and may be deposited to a thickness from about 800 angstroms to about 8,000 angstroms. After patterning and etching, the second passivation layer 28 has an opening therein exposing a portion of the conductive layer 24 for an electrical contact (e.g. bonding balls and bonding wires) to be bonded thereto.

FIG. 6 illustrates the further step of bonding an electrical contact 30 to the exposed portion of the conductive layer 24 according to one embodiment of the present invention. The bonding of the electrical contact 30 to the conductive layer 24 may be accomplished by any of the conventional and well-known wirebonding techniques, such as thermosonic bonding. Electrical contact 30 may be bonding balls or bonding wires and each bonding wire may be bonded directly to the surface of each conductive layer 24.

The chip may then be subjected to physical pressure tests. One of the problems which typically occurs during such testing is that the bond pads tend to exert pressure against the surrounding and lower dielectric layers forming cracks or otherwise damaging the dielectric layer in the region surrounding the bond pad. However, in the present invention, as bond attachment is performed above the passivation layer rather than on the bond pad as in the prior art methods of bonding, the bond pad structure of the present invention will be more robust and avoids the delamination problems associated with prior art bonding procedures. The passivation layers provide stress relief during the bonding process that substantially prevents the dielectric layers below the bond pad from cracking. In one embodiment, the bond pad 6 extends substantially directly below the exposed portion of the conductive layer 24. Delamination of dielectric layers may be further reduced in this fashion.

In accordance with the present invention, as the bonding balls or bonding wires are not formed on or near the scrub mark on the surface of the bond pad as in the prior art bonding methods, the bond pad structure of the present invention results in a stronger and more reliable mechanical bond and overall improved bonding reliability. Moreover, as bond attachment is performed above the passivation layer rather than on the bond pad as in the prior art methods of bonding, the bond pad structure of the present invention will be more robust and avoids the delamination problems associated with prior art bonding procedures. Testing has shown that a bond pad structure manufactured in accordance with the principals of the present invention substantially reduces the risk of damage to the circuit structure during the testing and bonding processes.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

What is claimed is:

1. A method for forming an integrated circuit, comprising:
providing a bond pad formed above a substrate;
depositing a first passivation layer above the bond pad, the first passivation having an opening therein exposing a portion of the bond pad;
depositing a conductive layer over the first passivation layer and the exposed bond pad;
patterning the conductive layer to expose portions of the first passivation layer; and
depositing a second passivation layer above the conductive layer and the exposed first passivation layer, the second passivation layer having an opening therein exposing a portion of the conductive layer.

2. The method of claim 1, further comprising bonding an electrical contact to the exposed portion of the conductive layer.

3. The method of claim 2, wherein the electrical contact comprises a bonding ball.

4. The method of claim 2, wherein the electrical contact comprises a bonding wire.

5. The method of claim 1, wherein the bond pad does not extend substantially directly below the exposed conductive layer portion.

6. The method of claim 1, wherein the bond pad extends substantially directly below the exposed conductive layer portion.

7. The method of claim 1, wherein the bond pad comprises aluminum.

8. A method of fabricating a bond pad structure in an integrated circuit, comprising:
providing a bond pad formed above a substrate;
depositing a first passivation layer above the bond pad, the first passivation having an opening therein exposing a portion of the bond pad;
depositing a conductive layer over the first passivation layer and the exposed bond pad;
patterning the conductive layer to expose portions of the first passivation layer; and
depositing a second passivation layer above the conductive layer and the exposed first passivation layer, the second passivation layer having an opening therein exposing a portion of the conductive layer, wherein the exposed conductive layer portion being distal from the bond pad.

9. The method of claim 8, further comprising bonding an electrical contact to the exposed portion of the conductive layer.

10. The method of claim 9, wherein the electrical contact comprises a bonding ball.

11. The method of claim 9, wherein the electrical contact comprises a bonding wire.

12. The method of claim 8, wherein the bond pad does not extend substantially directly below the exposed conductive layer portion.

13. The method of claim 8, wherein the bond pad extends substantially directly below the exposed conductive layer portion.

14. The method of claim 8, wherein the bond pad comprises aluminum.

15. An integrated circuit comprising:
a bond pad formed above a substrate;
a first passivation layer deposited above the bond pad, the first passivation layer having an opening therein exposing a portion of the bond pad;
a patterned conductive layer deposited above the first passivation layer and the exposed bond pad, the patterned conductive layer exposing portions of the first passivation layer; and
a second passivation layer deposited above the conductive layer and the exposed first passivation layer, the second passivation layer having an opening therein exposing a portion of the conductive layer, wherein the exposed conductive layer portion being distal from the bond pad.

16. The integrated circuit of claim 15, further comprising an electrical contact bonded to the exposed portion of the conductive layer.

17. The integrated circuit of claim 16, wherein the electrical contact comprises a bonding ball.

18. The integrated circuit of claim 16, wherein the electrical contact comprises a bonding wire.

19. The integrated circuit of claim 15, wherein the bond pad does not extend substantially directly below the exposed conductive layer portion.

20. The integrated circuit of claim 15, wherein the bond pad extends substantially directly below the exposed conductive layer portion.
